(19) United States
(12) Patent Application Publication
(10) Pub. No.: US 2015/0226811 A1
(43) Pub. Date: Aug. 13, 2015

(54) APPARATUS AND METHOD FOR ESTIMATING INTERNAL RESISTANCE OF BATTERY PACK

(71) Applicant: HON HAI PRECISION INDUSTRY CO., LTD., New Taipei (TW)

(72) Inventors: CHANG-YUAN SHIH, New Taipei (TW); HSIEN-HSI JUAN, New Taipei (TW)

(21) Appl. No.: 14/584,349

(22) Filed: Dec. 29, 2014

(30) Foreign Application Priority Data
Feb. 11, 2014 (TW) 103104352

(51) Int. Cl. G01R 31/36; H02J 7/00

(52) U.S. Cl. CPC G01R 31/3662; H02J 7/0021; G01R 31/3648; G01R 31/3624

(57) ABSTRACT

A method for estimating an internal resistance of a battery pack is disclosed. The method includes the steps of: detecting a terminal voltage and a charging current of the battery pack when a current constant charging to the battery pack is executed; estimating an initial state-of charge (SOC) of the battery pack at the time of starting the current constant charging of the battery pack; estimating an initial open-circuit voltage based on the initial SOC by referring to a relationship between the SOC and the open-circuit voltage; and calculating the internal resistance based on the initial open-circuit voltage, the terminal voltage, and the charging current.

### FIELD

The subject matter herein generally relates to batteries, and more particularly to an apparatus and method for estimating an internal resistance of a battery pack.

### BACKGROUND

An electric vehicle can use a battery including a plurality of secondary batteries, which could be charged and discharged and formed in a single pack, as a main power source. Since the performance of a battery may have a direct effect on the performance of the vehicle, the performance of each battery cell is important. An internal resistance of the battery is a very important parameter that reflects a state-of-health (SOH) of the battery. That is, the internal resistance of the battery is a good indicator of expected life. Therefore, it can be beneficial to have an accurate and convenient estimate of battery internal resistance.

### BRIEF DESCRIPTION OF THE DRAWINGS

Implementations of the present technology will now be described, by way of example only, with reference to the attached figures.

FIG. 1 is a block diagram of one embodiment of an apparatus for estimating an internal resistance of a battery pack.

FIG. 2 is a graph showing relationship between a state-of charge (SOC) of the battery pack and an open-circuit voltage of the battery pack.

FIG. 3 is a circuit diagram of the battery pack.

FIG. 4 is a flowchart of one embodiment of a method for estimating an internal resistance of a battery pack.

FIG. 5 is a detailed flow chart of a block 402 of the method as shown in FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series and the like.

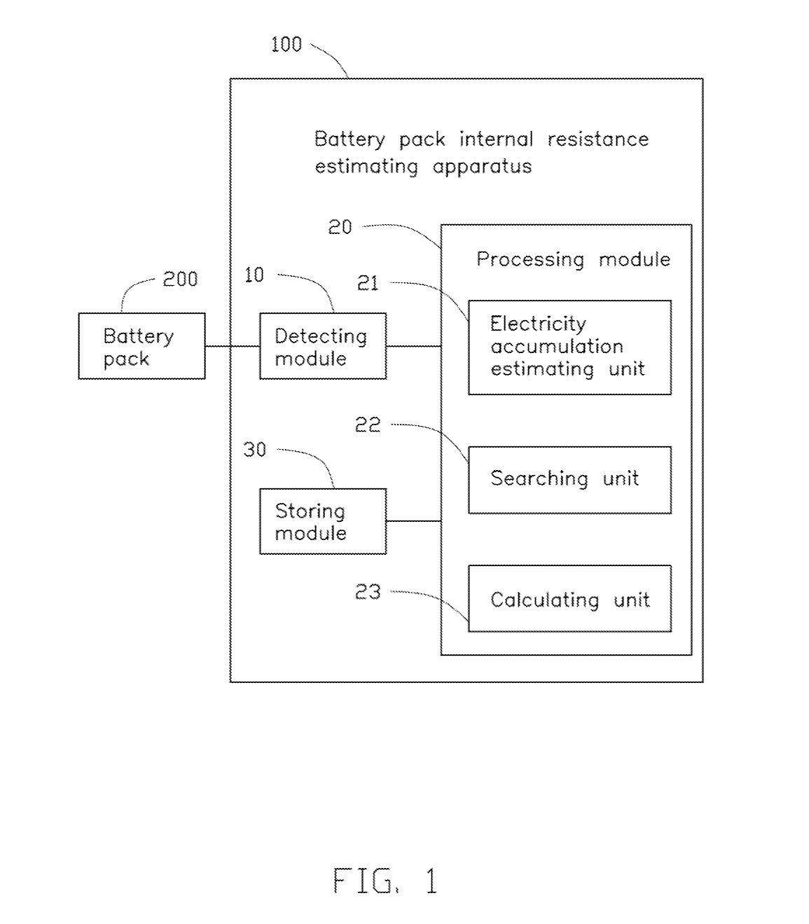

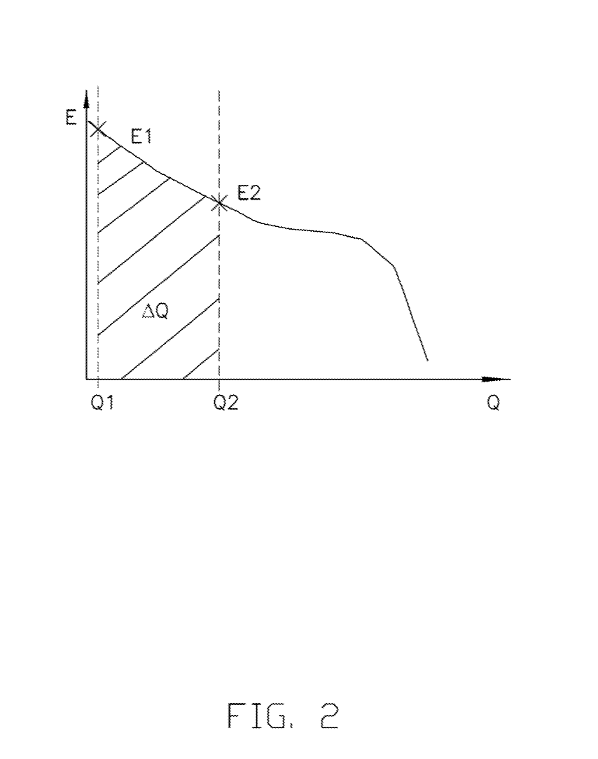

FIG. 1 illustrates a block diagram of one embodiment of a battery pack internal resistance estimating apparatus 100. The apparatus 100 is configured to estimate an internal resistance of a battery pack 200 when the battery pack 200 is charged by current constant charging. The term “current constant charging” means the battery pack 200 is charged with a constant current. The apparatus 100 includes a detecting module 10, a processing module 20, and a storing module 30. The processing module 20 includes an electricity accumulation estimating unit 21, a searching unit 22, and a calculating unit 23. The storing module 30 stores a relationship between a state-of charge (SOC) Q(t) of the battery pack 200 and an open-circuit voltage E(t) of the battery pack 200. The SOC Q(t) indicates how much the battery pack 200 is charged or how much dischargeable the battery pack 200. In other words, the SOC Q(t) indicates a residual electricity of the battery pack 200. The processing module 20 may estimate the SOC Q(t) based on the open-circuit voltage E(t) by referring to the relationship stored in storing module 30. On the other hand, the processing module 20 may also estimate the open-circuit voltage E(t) based on the SOC Q(t) by referring to the relationship stored in the storing module 30. The data of the relationship stored in the storing module 30 can be collected by a large number of tests of the battery pack 200. In at least one embodiment, the relationship is presented as a graph as shown in FIG. 2. More details about the modules of the apparatus 100 will be described below.

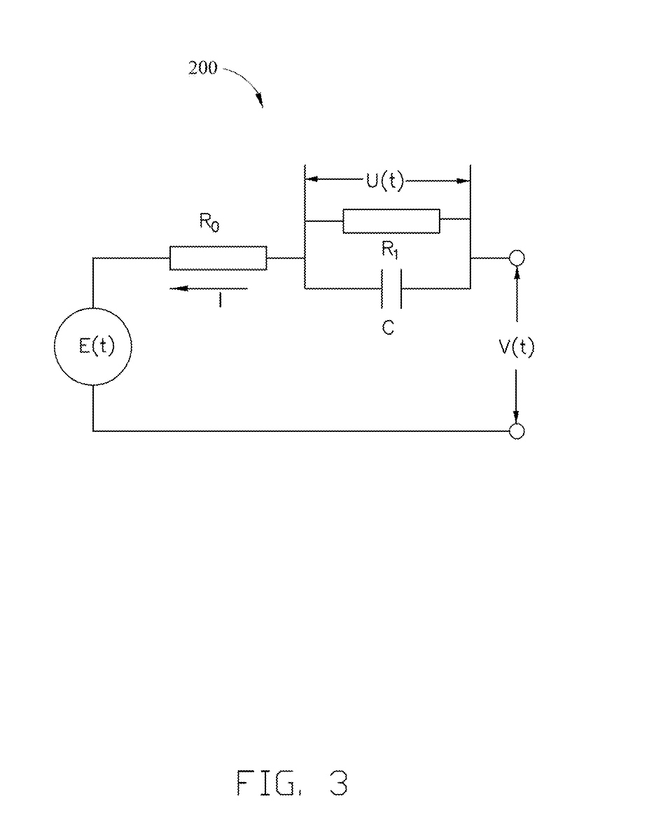

FIG. 3 illustrates a circuit diagram of the battery pack 200. A terminal voltage (voltage between the terminals) of the battery pack 200 is given by: V(t)=E(t)+R₀I+u(t), where: V(t) represents the terminal voltage of the battery pack 200; E(t) represents the open-circuit voltage of the battery pack 200; R₀ represents a ohmic resistance (electronic resistance) of the battery pack 200; I represents a charging current flowing through the battery pack 200; and u(t) represents a voltage of a ionic resistance R₁ of the battery pack 200. The ohmic resistance R₀ plus the ionic resistance R₁ is referred as the internal resistance (total effective resistance) of the battery pack 200. When the battery pack 200 is charged by a current constant charging, a capacitor C connected to the ionic resistance R₁ in parallel can be treated as a open circuit, such that a equation V(t)=E(t)+(R₀+R₁)I can be obtained. Thus, the internal resistance of the battery pack 200 can be calculated using the equation V(t)=E(t)+(R₀+R₁)I based on the terminal voltage V(t), the open-circuit voltage E(t), and the charging current I flowing through the battery pack 200.

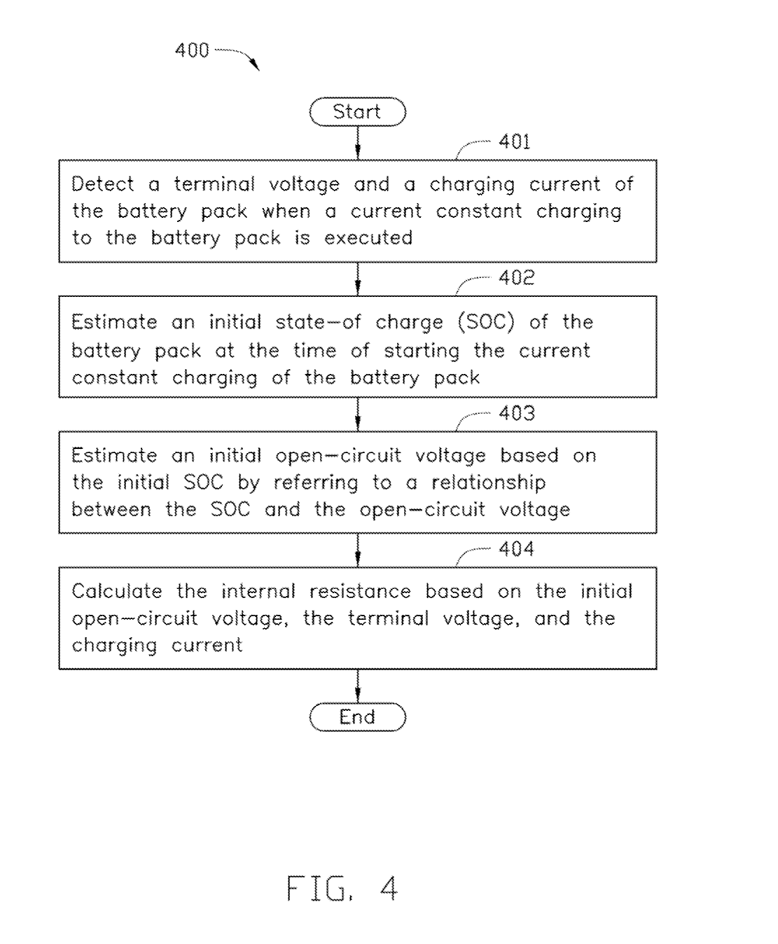

Referring to FIG. 4, a flowchart is presented in accordance with an example embodiment which is being thus illustrated. The example method 400 is provided by way of example, as there are a variety of ways to carry out the method. The method 400 described below can be carried out using the configurations illustrated in FIG. 1, for example, and various elements of these figures are referenced in explaining example method 400. Each block shown in FIG. 4 represents one or more processes, methods or subroutines, carried out in the exemplary method 400. Furthermore, the illustrated order of blocks is by example only and the order of the blocks can change according to the present disclosure. Additional blocks may be added or fewer blocks may be utilized, without departing from this disclosure. The exemplary method 400 can begin at block 401.

At block 401, the detecting module 10 detects the terminal voltage V(t) and the charging current I of the battery pack 200 when a current constant charging to the battery pack 200 is executed.

At block 402, the processing module 20 estimates an initial SOC Q1 of the battery pack 200 at the time of starting the current constant charging of the battery pack 200.

At block 403, the searching unit 22 estimates an initial open-circuit voltage E1 based on the initial SOC Q1 by referring to the relationship stored in the storing module 30.

At block 404, the calculating module 23 calculates the internal resistance of the battery pack 200 using the equation V(t)=E(t)+(R₀+R₁)I (where E(t)=E1) based on the detected terminal voltage V(t), the detected charging current I, and the initial open-circuit voltage E(1).

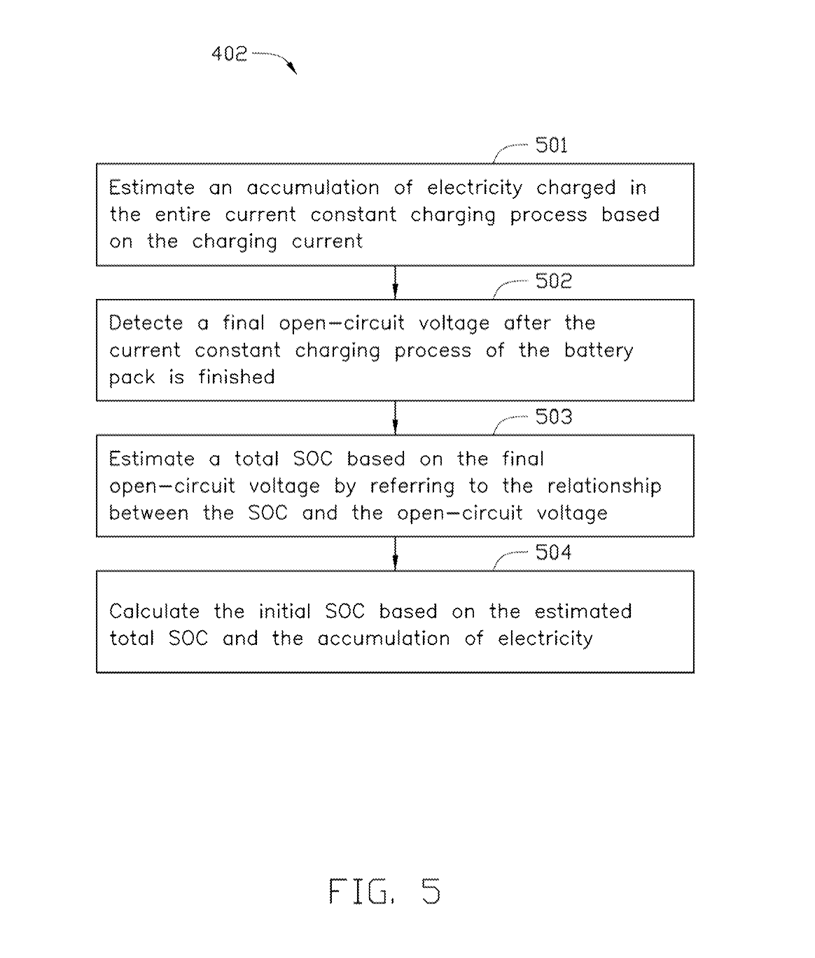

FIG. 5 illustrates a detailed flow chart of the block 402 as shown in FIG. 4. Depending on the embodiment, additional blocks can be added, others removed, and the ordering of the blocks can be changed.

At block 501, the electricity accumulation estimating unit 21 estimates an accumulation of electricity ΔQ (also see FIG. 2) charged in the entire current constant charging process based on the charging current I. The electricity accumulation estimating unit 21 can be a coulomb counter, which estimates the accumulation of electricity ΔQ using a Coulomb integral method based on the charging current I.

At block 502, the detecting module 10 detects a final open-circuit voltage E2 after the current constant charging process of the battery pack 200 is finished. In at least one embodiment, for improving the accuracy of the estimate of the internal resistance, the detecting module 10 detects the final open-circuit voltage E2 after the current constant charging process of the battery pack 200 is finished for a while.

At block 503, the searching unit 22 estimates a total SOC Q2 (also see FIG. 2) based on the final open-circuit voltage E2 by referring to the relationship stored in the storing module 30.

At block 504, the calculating unit 23 calculates the initial SOC Q1 using an equation Q1=Q2−ΔQ (also see FIG. 2) based on the estimated total SOC Q2, and estimated accumulation of electricity ΔQ.

In summary, the apparatus 100 and method 400 can estimate the internal resistance of the battery pack 200 when the battery pack 200 is charged by current constant charging. Since the battery pack 200 has a stable battery characteristic and a simple equivalent circuit model when it is charged by current constant charging, the aforementioned apparatus 100 and method 400 can estimate the internal resistance of the battery pack 200 more accuracy and convenient.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method for estimating an internal resistance of a battery pack comprising:
detecting a terminal voltage and a charging current of the battery pack when a current constant charging to the battery pack is executed;
estimating an initial state-of charge (SOC) of the battery pack at a time of starting the current constant charging of the battery pack;
estimating an initial open-circuit voltage based on the initial SOC by referring to a relationship between the SOC and the open-circuit voltage; and
calculating the internal resistance based on the initial open-circuit voltage, the terminal voltage, and the charging current.

2. The method of claim 1, wherein the step of estimating an initial state-of charge SOC of the battery pack comprises:
estimating an accumulation of electricity charged in the entire current constant charging process based on the charging current;
detecting a final open-circuit voltage after the current constant charging process of the battery pack is finished;
estimating a total SOC based on the final open-circuit voltage by referring to the relationship between the SOC and the open-circuit voltage; and
calculating the initial SOC based on the estimated total SOC, and the accumulation of electricity.

3. The method of claim 2, wherein the step of estimating an accumulation of electricity by using a Coulomb integral method based on the charging current.

4. The method of claim 1, wherein the step of calculating the internal resistance comprises:
calculating the internal resistance using an equation V(t)=E(1)+(R₀+R₁)I based on the initial open-circuit voltage, the terminal voltage, and the charging current; where V(t) represents the terminal voltage; I represents the charging current; E(1) represents the initial open-circuit voltage; and R₀+R₁represent the internal resistance of the battery pack.

5. An apparatus for estimating an internal resistance of a battery pack comprising:
a storing module configured to store a relationship between a state-of charge (SOC) of the battery pack and an open-circuit voltage of the battery pack;
a detecting module configured to detect a terminal voltage and a charging current of the battery pack when a current constant charging to the battery pack is executed; and
a processing module configured to estimate an initial state-of charge (SOC) of the battery pack at a time of starting the current constant charging of the battery pack, the processing module comprising:
a searching unit configured to estimate an initial open-circuit voltage based on the initial SOC by referring to a relationship between the SOC and the open-circuit voltage; and
a calculating unit configured to calculate the internal resistance based on the initial open-circuit voltage, the terminal voltage, and the charging current.

6. The apparatus of claim 5, wherein the processing module further comprises:
an electricity accumulation estimating unit configured to estimate an accumulation of electricity charged in the entire current constant charging process based on the charging current;
the detecting module further configured to detect a final open-circuit voltage after the current constant charging process of the battery pack is finished;
the searching unit further configured to estimate a total SOC based on the final open-circuit voltage by referring to the relationship between the SOC and the open-circuit voltage; and
the calculating unit is further configured to calculate the initial SOC based on the estimated total SOC, and the accumulation of electricity.

7. The apparatus of claim 6, wherein the electricity accumulation estimating unit is a Coulomb counter, and configured to estimate the accumulation of electricity by using a Coulomb integral method based on the charging current.

8. The apparatus of claim 5, wherein the calculating unit calculates the internal resistance using an equation V(t)=E(1)+(R₀+R₁)I based on the initial open-circuit voltage, the terminal voltage, and the charging current; where V(t) represents the terminal voltage; I represents the charging current; E(1) represents the initial open-circuit voltage; and R₀+R₁ represent the internal resistance of the battery pack.
